(19) United States
(12) Patent Application Publication
(10) Pub. No.: US 2025/0355355 A1
(43) Pub. Date: Nov. 20, 2025

(54) PHOTOSENSITIVE RESIN COMPOSITION, PHOTOSENSITIVE RESIN LAYER USING THE SAME, DISPLAY DEVICE, AND MANUFACTURING METHOD OF PHOTOSENSITIVE RESIN LAYER

(71) Applicant: SAMSUNG SDI CO., LTD., Yongin-si (KR)

(72) Inventors: Heejo MOON, Suwon-si (KR); Subin PARK, Suwon-si (KR); Ickjin KIM, Suwon-si (KR); Kwangwon SEO, Suwon-si (KR); Baek Soung PARK, Suwon-si (KR)

(21) Appl. No.: 18/923,945

(22) Filed: Oct. 23, 2024

(30) Foreign Application Priority Data
May 20, 2024 (KR) 10-2024-0065471

(51) Int. Cl. G03F 7/038; G03F 7/039; H10K 59/38; H10K 59/80

(52) U.S. Cl. CPC G03F 7/0384; G03F 7/039; H10K 59/38; H10K 59/873

(57) ABSTRACT

A photosensitive resin composition including a polymer resin having a refractive index of greater than or equal to about 1.66; a photopolymerizable monomer; a photopolymerization initiator; and a solvent, wherein the polymer resin has a repeating structural unit, and the structural unit includes a moiety derived from an acid dianhydride.

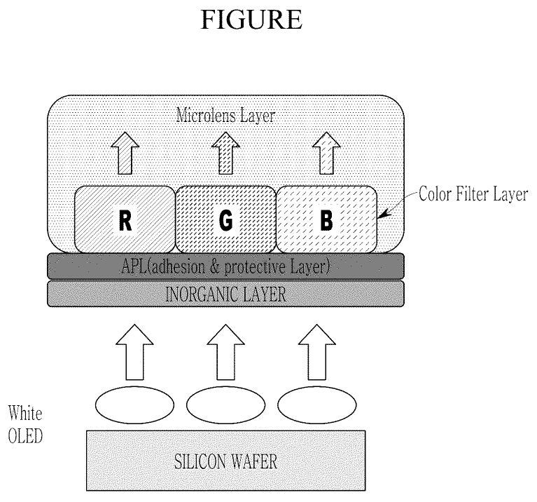

### CROSS-REFERENCE TO RELATED APPLICATION

This application claims priority to and the benefit of Korean Patent Application No. 10-2024-0065471 filed in the Korean Intellectual Property Office on May 20, 2024, the entire contents of which are incorporated herein by reference.

### BACKGROUND

### 1. Field

Embodiments relate to a photosensitive resin composition, a photosensitive resin layer using the same, a display device, and a method of manufacturing the photosensitive resin layer.

### 2. Description of the Related Art

Recently, interest in self-emitting (emissive) micro OLED display panels, which may be applied to VR (Virtual Reality), AR (Augmented Reality), and MR (Mixed Reality) devices, is increasing.

### SUMMARY

Embodiments are directed to a photosensitive resin composition, including a polymer resin having a refractive index of greater than or equal to about 1.66; a photopolymerizable monomer; a photopolymerization initiator; and a solvent, wherein the polymer resin has a repeating structural unit, and the structural unit includes a moiety derived from an acid dianhydride.

The structural unit may further include a moiety including one or more sulfur atoms.

The moiety including one or more sulfur atoms may include a structure represented by one of Chemical Formula 1 to Chemical Formula 3:

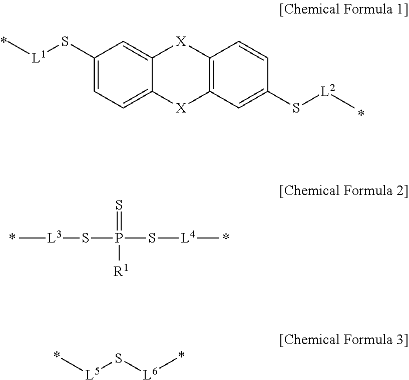

wherein in Chemical Formula 1 to Chemical Formula 3, X may be *—S—* or *—S(═O)₂—*, R1 may be a substituted or unsubstituted C1 to C20 alkyl group or a substituted or unsubstituted C6 to C20 aryl group, and L1 to L6 may each independently be a substituted or unsubstituted C1 to C20 alkylene group or a substituted or unsubstituted C6 to C20 arylene group.

The moiety including one or more sulfur atoms may include one of Chemical Formula 1-1, Chemical Formula 1-2, Chemical Formula 2-1 or Chemical Formula 3-1:

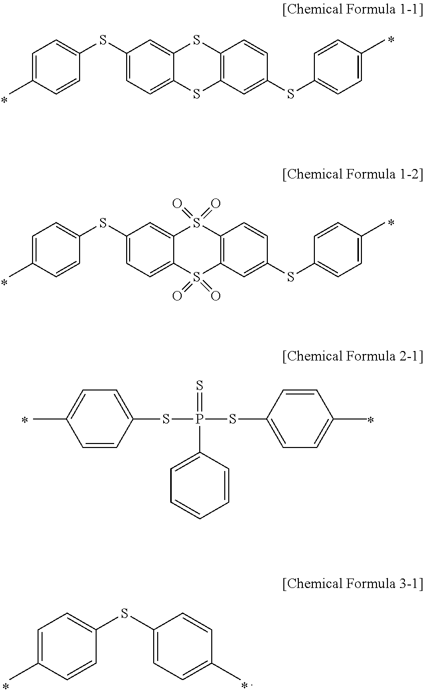

The moiety derived from the acid dianhydride may include a structure represented by Chemical Formula 4-1 or Chemical Formula 4-2:

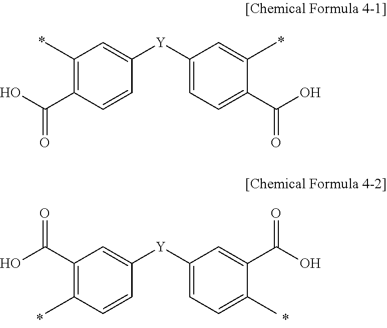

wherein in Chemical Formula 4-1 and Chemical Formula 4-2 Y is a single bond or *—C(═O)—*.

The repeating structural unit in the polymer resin may be represented by one of Chemical Formula 5 to Chemical Formula 8:

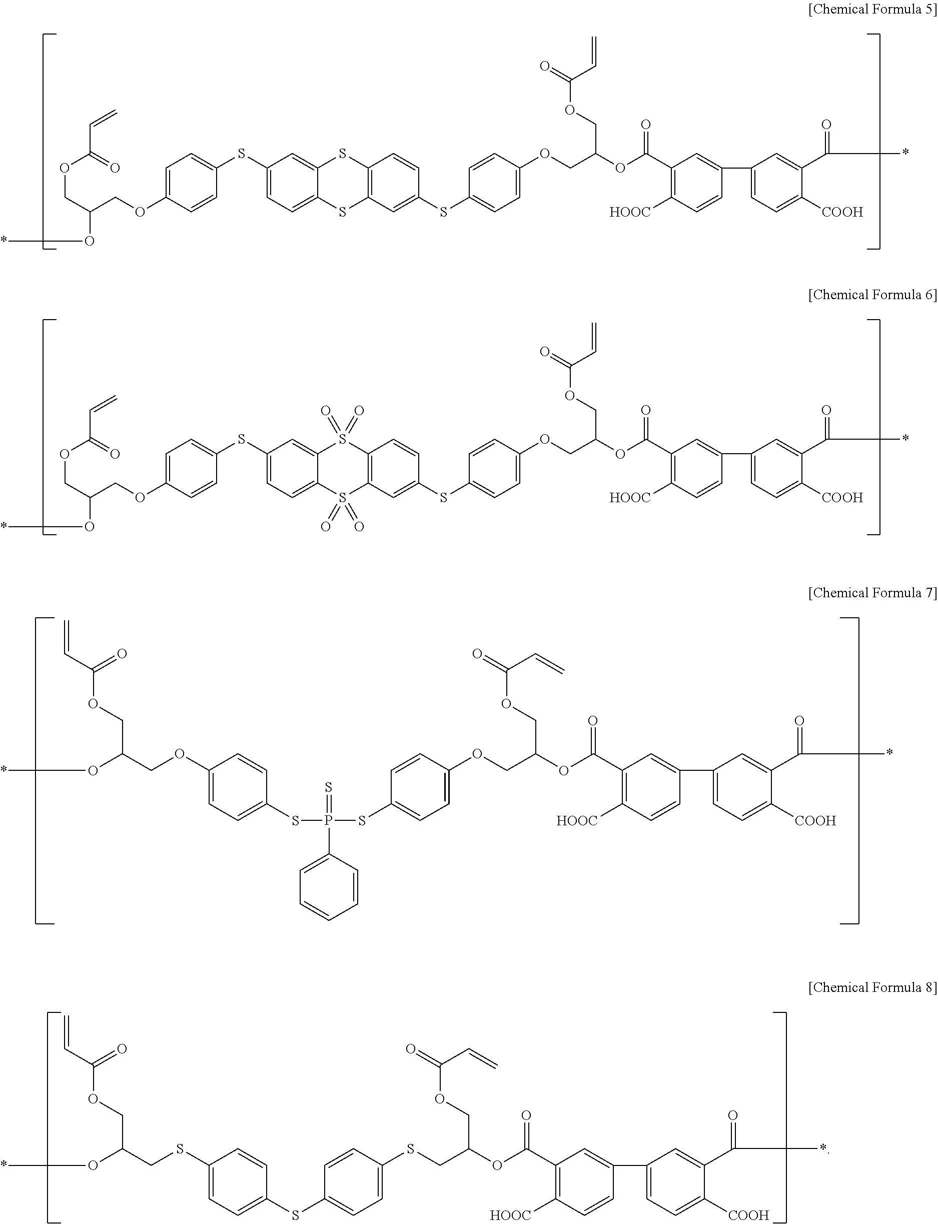

The polymer resin may be included in an amount of about 10 wt % to about 30 wt %, based on a total weight of the photosensitive resin composition.

The polymer resin may have a weight average molecular weight of about 20,000 g/mol to about 80,000 g/mol.

The photosensitive resin composition may include, based on a total weight of the photosensitive resin composition about 10 wt % to about 30 wt % of the polymer resin; about 3 wt % to about 15 wt % of the photopolymerizable monomer; and about 0.1 wt % to about 5 wt % of the photopolymerization initiator.

The photosensitive resin composition may further include malonic acid, 3-amino-1,2-propanediol, a silane coupling agent, a leveling agent, a surfactant, a polymerization inhibitor, or a combination thereof.

The embodiments may be realized by providing a photosensitive resin layer manufactured using the photosensitive resin composition according to an embodiment.

The embodiments may be realized by providing a display device including the photosensitive resin layer according to an embodiment.

The display device may be a micro OLED display device including an OLED substrate on a silicon wafer and a color filter layer located on the OLED substrate and configured to convert white light generated from the OLED substrate into a plurality of color lights, the photosensitive resin layer may be located on the OLED substrate and color filter layer, and the color filter layer may include a red color filter, a green color filter, and a blue color filter.

The embodiments may be realized by providing a method of manufacturing a photosensitive resin layer that may include coating the photosensitive resin composition according to an embodiment; prebaking at a temperature of about 100° C. or lower after the coating; and exposing to i-line after the prebaking, and developing after the exposing.

Embodiments are directed to a photosensitive resin composition, including a polymer resin having a refractive index of greater than or equal to about 1.62; a photopolymerizable monomer; a photopolymerization initiator; and a solvent, wherein the polymer resin has a repeating structural unit, and the structural unit includes a moiety derived from an acid dianhydride.

### BRIEF DESCRIPTION OF THE DRAWING

Features will become apparent to those of skill in the art by describing in detail exemplary embodiments with reference to the attached drawing in which:

the FIGURE is a schematic diagram showing the structure of a micro OLED display device according to some example embodiments.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B. As used herein, hydrogen substitution (—H) may include deuterium substitution (-D) or tritium substitution (-T). For example, any hydrogen in any compound described herein may be protium, deuterium, or tritium (e.g., based on natural or artificial substitution).

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen of a compound by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate”, and “(meth)acrylic acid” refers to “acrylic acid” and “methacrylic acid”.

As used herein, when a definition is not otherwise provided, the term “combination” refers to mixing or copolymerization. Additionally, “copolymerization” refers to block copolymerization or to random copolymerization, and “copolymer” refers to block copolymerization or to random copolymerization.

In the chemical formula of the present specification, unless a specific definition is otherwise provided, hydrogen is bonded at the position when a chemical bond is not drawn where supposed to be given.

As used herein, when a definition is not otherwise provided, “*” refers to a linking part between the same or different atoms, or chemical formulas.

A photosensitive resin composition according to some example embodiments may include, e.g., a polymer resin having a refractive index of greater than or equal to about 1.66; a photopolymerization initiator; and a solvent, wherein the polymer resin has a repeating structural unit, and the structural unit includes a moiety derived from an acid dianhydride.

Some photoresists may be negative photosensitive liquid materials implemented in color patterns of red, green, and blue, and technology development has been made in the direction of gradually modifying the composition of such liquid materials. Efforts have been made to improve color purity by modifying the type or content of the pigment dispersion, which may be a coloring material that implements the color pattern, to improve patternability by modifying the composition of the binder resin or photopolymerization initiator, or to improve coating properties and color uniformity through the use of other additives such as leveling agents.

The present embodiments are not related to a color photoresist used in the manufacture of some color filters, e.g., those described above, but are for a microlens applied to a micro OLED display device. The microlens may have excellent adhesion to a low-temperature cured color filter and may therefore be applied to a display device including the low-temperature cured color filter.

Micro displays are technologies that transmit image information through an optical system to a display with a screen size of 1 inch or less. Herein, because a high resolution must be implemented in a very small region, CMOS backplane of an Si wafer substrate is used

Among them, micro OLED displays may use OLEDs as a backlight to emit light and may require low-temperature cured color filters. On the other hand, as pixel sizes become smaller, high-sensitivity materials may be required for reproducing accurate light colors.

Because the conventional semiconductor CMOS process uses HDMS deposition to adhere the color filters, wherein a low-temperature curing process may be difficult, there has been a lot of research on alternative materials in order to solve this problem. After extensive research, the inventors developed a photosensitive resin composition for microlenses that is capable of low-temperature curing while also having excellent developability and fine patternability.

Specifically, the photosensitive resin composition according to some example embodiments is a low-temperature curable transparent material, has high adhesion to a color filter, little residue (excellent developability), and excellent pattern linearity (excellent fine patternability). In particular, the photosensitive resin composition according to some example embodiments, which may be a transparent material, may be suitably applied to display devices for VR (Virtual Reality), AR (Augmented Reality), and MR (Mixed Reality), which are next generation displays requiring transparency (crack prevention) and precise patterning for being fitted in required regions, e.g., micro OLED display devices. In other words, the photosensitive resin composition according to some example embodiments may be a colorant-free composition, e.g., a transparent photosensitive resin composition and thus may also exhibit excellent transmittance.

In an implementation, the photosensitive resin composition according to some example embodiments may improve residue characteristics (developability) and pattern linearity (fine patternability) by controlling the refractive index of the polymer resin, specifically, the refractive index of the polymer resin at 550 nm, to greater than or equal to about 1.66.

Hereinafter, each component is described in detail.

### (A) Polymer Resin

As described above, the photosensitive resin composition according to some example embodiments may include a polymer resin, wherein a refractive index of the polymer resin at 550 nm may be controlled to significantly improve residue characteristics, pattern linearity, and adhesion to a color filter. In an implementation, the polymer resin may have a refractive index at 550 nm, e.g., at a wavelength of 550 nm, in a range of about 1.66 to about 1.8, e.g., about 1.66 to about 1.75, about 1.66 to about 1.7, about 1.67 to about 1.8, or about 1.68 to about 1.8.

In order to control the refractive index at 550 nm as shown above, the polymer resin in the photosensitive resin composition according to some example embodiments includes a repeating structural unit, wherein the structural unit may include two residual groups, e.g., a moiety derived from acid dianhydride and a moiety including one or more sulfur atoms.

In an implementation, the moiety including one or more sulfur atoms may include at least two sulfur atoms, e.g., at least four sulfur atoms. The more the sulfur atoms, the higher the refractive index of the polymer resin at 550 nm may be, thereby maximizing the improvement in developability and pattern linearity.

In an implementation, the polymer resin may include the moiety derived from acid dianhydride.

If the polymer resin includes the moiety including one or more sulfur atoms alone, the refractive index at 550 nm may be difficult to control to be about 1.66 or higher, resulting in deteriorating the developability and pattern linearity. In an implementation, the resin may be a polymer resin, but if a monomolecular resin is used, even though the refractive index at 550 nm may be controlled within the range, compatibility with other components, e.g., a photopolymerizable monomer or a photopolymerization initiator may be deteriorated, resulting in very inferior developability and pattern linearity.

In an implementation, the moiety including one or more sulfur atoms may include a structure represented by one of Chemical Formula 1 to Chemical Formula 3.

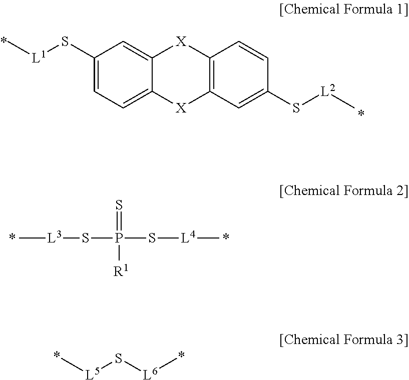

In Chemical Formula 1 to Chemical Formula 3, X may be, e.g., *—S—*, or *—S(═O)₂—*.

R¹ may be or include, e.g., a substituted or unsubstituted C1 to C20 alkyl group or a substituted or unsubstituted C6 to C20 aryl group.

L¹ to L⁶ may each independently be or include, e.g., a substituted or unsubstituted C1 to C20 alkylene group or a substituted or unsubstituted C6 to C20 arylene group.

In an implementation, the moiety including one or more sulfur atoms may include, e.g., a structure represented by one of Chemical Formula 1-1, Chemical Formula 1-2, Chemical Formula 2-1, or Chemical Formula 3-1.

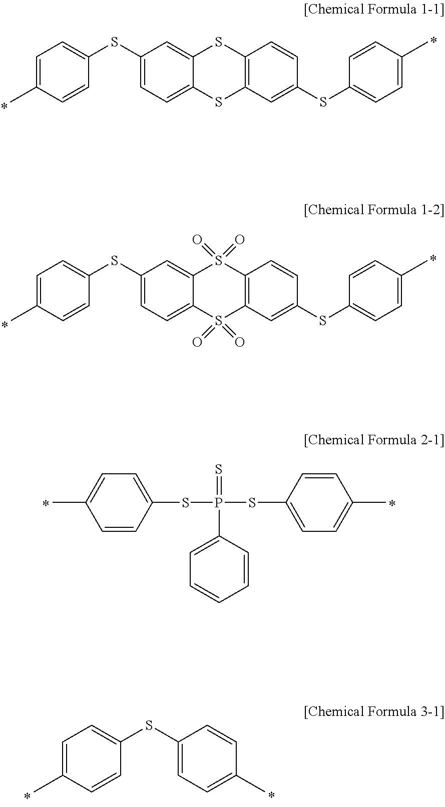

In an implementation, the moiety derived from the acid dianhydride may include, e.g., a structure represented by one of Chemical Formula 4-1 or Chemical Formula 4-2.

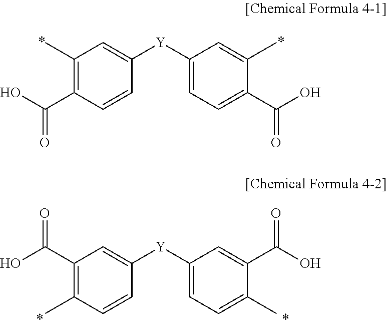

In Chemical Formula 4-1 and Chemical Formula 4-2, Y may be, e.g., a single bond or *—C(═O)—*.

In an implementation, the repeating structural unit in the polymer resin may be represented by, e.g., one of Chemical Formula 5 to Chemical Formula 8.

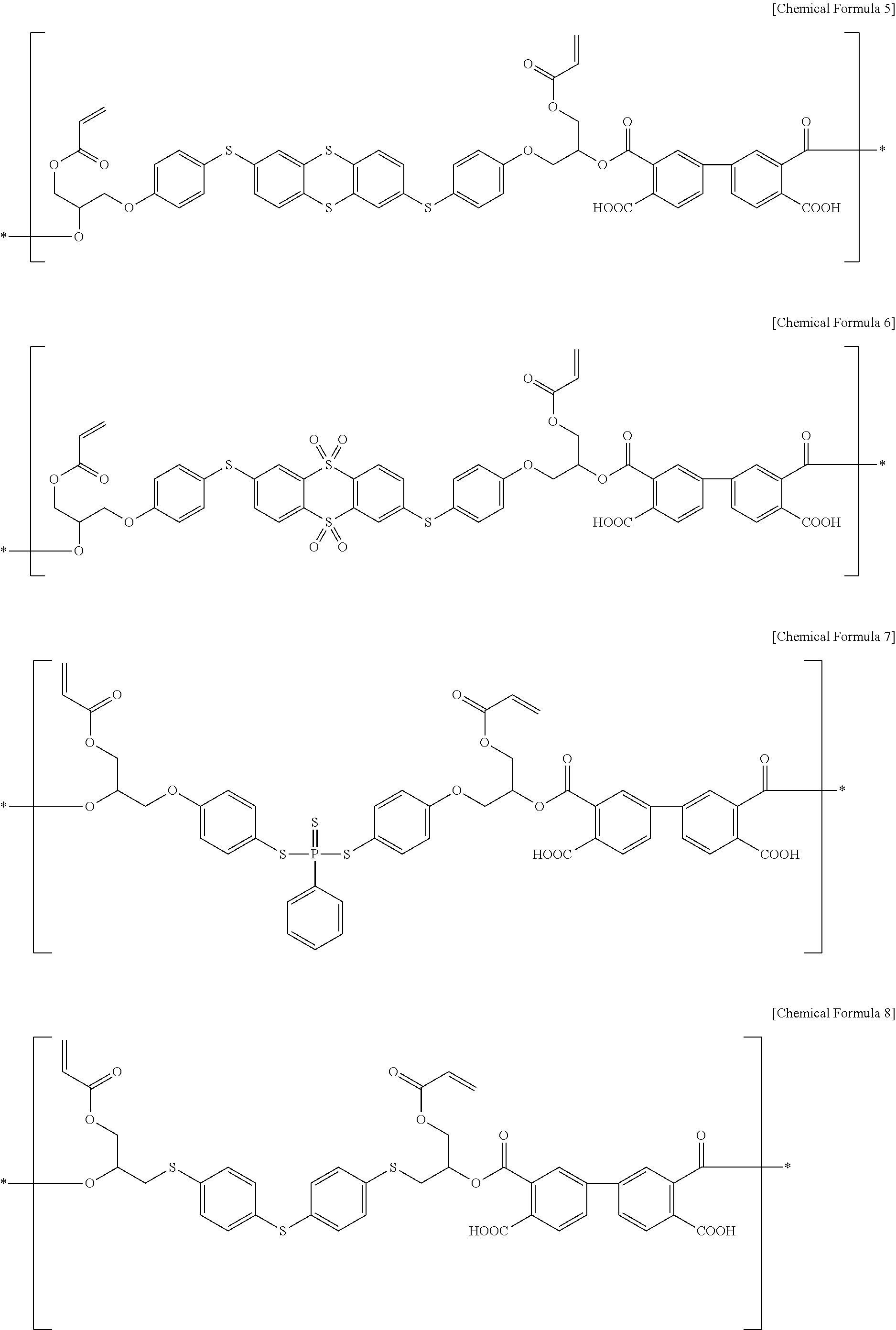

In an implementation, the polymer resin may be included in an amount of about 10 wt % to about 30 wt %, e.g., about 15 wt % to about 25 wt %, based on a total weight of the photosensitive resin composition. In an implementation, the polymer resin may be included in an amount of about 40 wt % to about 80 wt %, e.g., about 50 wt % to about 70 wt %, based on a total solid content of the photosensitive resin composition. Maintaining the weight of the polymer resin within the above range may help ensure that a difference between the refractive index at 550 nm of the photosensitive resin composition according to some example embodiments and the refractive index of the polymer resin at 550 nm may be minimized, ultimately maximizing the improvement in the developability and pattern linearity of the photosensitive resin composition.

In an implementation, the polymer resin may have a weight average molecular weight of about 20,000 g/mol to about 80,000 g/mol. Maintaining the weight average molecular weight of the polymer resin within the above range may help ensure that compatibility with other components, e.g., a photopolymerizable monomer and a photopolymerization initiator, described below, can be improved.

In an implementation, the photosensitive resin composition according to some example embodiments may further include, in addition to the polymer resin, a binder resin, e.g., an acrylic binder resin, an epoxy binder resin, or a combination thereof.

The acrylic binder resin may be, e.g., a copolymer of a first ethylenically unsaturated monomer and a second ethylenically unsaturated monomer copolymerizable therewith, and may be a resin including one or more acrylic repeating units.

The first ethylenically unsaturated monomer may be, e.g., an ethylenically unsaturated monomer including at least one carboxyl group, and examples thereof may include, e.g., acrylic acid, methacrylic acid, maleic acid, itaconic acid, fumaric acid, or a combination thereof.

The first ethylenically unsaturated monomer may be included in an amount of 5 wt % to 50 wt %, e.g., 10 wt % to 40 wt %, based on a total weight of the acrylic binder resin.

Examples of the second ethylenic unsaturated monomer may include, e.g., an aromatic vinyl compound such as styrene, α-methylstyrene, vinyltoluene, vinylbenzylmethylether, or the like; an unsaturated carboxylic acid ester compound, e.g., methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated carboxylic acid amino alkyl ester compound, e.g., 2-aminoethyl(meth)acrylate, 2-dimethylaminoethyl(meth)acrylate, or the like; a carboxylic acid vinyl ester compound, e.g., vinyl acetate, vinyl benzoate, or the like; an unsaturated carboxylic acid glycidyl ester compound, e.g., glycidyl(meth)acrylate or the like; a vinyl cyanide compound, e.g., (meth)acrylonitrile or the like; an unsaturated amide compound, e.g., (meth)acrylamide or the like; or the like, and may be used alone or as a mixture of two or more.

Examples of the acrylic binder resin may include, e.g., a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer or the like, and may be used alone or as a mixture of two or more.

The acrylic binder resin may have an acid value of, e.g., about 30 KOHmg/g to about 180 KOHmg/g and a weight average molecular weight of, e.g., about 3,000 g/mol to about 20,000 g/mol. Maintaining the acid value and weight average molecular weight of the acrylic binder resin within the above ranges may help ensure it has excellent pattern formation properties, and that the produced thin film may have excellent mechanical and thermal characteristics.

If the epoxy binder resin is additionally included in the photosensitive resin composition according to some example embodiments, heat resistance may be improved. The epoxy binder resin may include, e.g., phenol novolac epoxy resin, tetramethyl biphenyl epoxy resin, bisphenol A type epoxy resin, bisphenol F type epoxy resin, alicyclic epoxy resin, or a combination thereof.

### (B) Photopolymerizable Monomer

The photopolymerizable monomer in the photosensitive resin composition according to some example embodiments may be, e.g., a single compound or a mixture of two different types of compounds.

In an implementation, the photopolymerizable monomer may be, e.g., a mono-functional or a multi-functional ester of (meth)acrylic acid including at least one ethylenic unsaturated double bond.

The photopolymerizable monomer may have the ethylenic unsaturated double bond and thus, may cause sufficient polymerization during exposure in a pattern-forming process and may form a pattern having excellent heat resistance, light resistance, and chemical resistance.

Examples of the photopolymerizable monomer may include, e.g., ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, ethoxylated bisphenyl fluorene diacrylate, ethoxylated naphthalene type diacrylate, ethoxylated sulfur type diacrylate, or the like.

Examples of the mono-functional ester of (meth)acrylic acid may include, e.g., Aronix® M-101™, M-111™, or M-114™ (Toagosei Chemistry Industry Co., Ltd.); KAYARAD® TC-110S™ or TC-120S™ (Nippon Kayaku Co., Ltd.); V-158™, V-2311™ (Osaka Organic Chemical Ind., Ltd.), or the like. Examples of a difunctional (meth)acrylic acid ester may include, e.g., Aronix® M-210™, M-240™, or M-6200™ (Toagosei Chemistry Industry Co., Ltd.), KAYARAD® HDDA™, HX-220™, or R-604™ (Nippon Kayaku Co., Ltd.), V-260™, V-312™, V-335 HP™ (Osaka Organic Chemical Ind., Ltd.), BPF-022™, BPF-022B™, BPF-022L™, BPF-022G™, BPF-102™, BPF-152™, BPF-202™, BPF-302™, BN-042™, BN-102™, TBP-042™, TBP-102™ (Hannong Chemicals Inc.), or the like. Examples of a tri-functional ester of (meth)acrylic acid may include, e.g., Aronix® M-309™, M-400™, M-405™, M-450™, M-710™, M-8030™, or M-8060™ (Toagosei Chemistry Industry Co., Ltd.), KAYARAD® TMPTA, DPCA-20™, DPCA-30™, DPCA-60™, or DPCA-120™ (Nippon Kayaku Co., Ltd.), V-295™, V-300™, V-360™, V-GPT™, V-3PA™, V-400™ (Osaka Yuki Kayaku Kogyo Co. Ltd.), or the like. These may be used alone or as a mixture of two or more.

The photopolymerizable monomer may be treated with acid anhydride to improve developability. In an implementation, the photopolymerizable monomer may be included in an amount of about 3 wt % to about 15 wt %, e.g., about 5 wt % to about 10 wt %, based on a total weight of the photosensitive resin composition. In an implementation, the photopolymerizable monomer may be included in an amount of about 20 wt % to about 60 wt %, e.g., about 30 wt % to about 50 wt %, based on a total weight of solids constituting the photosensitive resin composition. Including the photopolymerizable monomer within the above ranges may help ensure that the photopolymerizable monomer is sufficiently cured during exposure in a pattern-forming process and has excellent reliability, and that developability for alkali developing solution may be improved.

### (C) Photopolymerization Initiator

The photosensitive resin composition according to some example embodiments may include a photopolymerization initiator. The photopolymerization initiator may include an acetophenone compound, a benzophenone compound, a thioxanthone compound, a benzoin compound, a triazine compound, an oxime compound, or the like.

Examples of the acetophenone compound may include, e.g., 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, or the like.

Examples of the benzophenone compound may include, e.g., benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, or the like.

Examples of the thioxanthone compound may include, e.g., thioxanthone, 2-chlorothioxanthone, 2-methylthioxanthone, isopropyl thioxanthone, 2,4-diethyl thioxanthone, 2,4-diisopropyl thioxanthone, or the like.

Examples of the benzoin compound may include, e.g., benzoin, benzoin methyl ether, benzoin ethyl ether, benzoin isopropyl ether, benzoin isobutyl ether, benzyl dimethyl ketal, or the like.

Examples of the triazine compound may include, e.g., 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, or the like.

Examples of the oxime compound may include, e.g., an O-acyloxime compound, 2-(O-benzoyloxime)-1-[4-(phenylthio)phenyl]-1,2-octanedione, or 1-(O-acetyloxime)-1-[9-ethyl-6-(2-methylbenzoyl)-9H-carbazol-3-yl]ethenone. Specific examples of the O-acyloxime compound may be, e.g., 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-one, oxime-O-acetate, or the like.

In an implementation, the photopolymerization initiator may also be used together with, e.g., a carbazole compound, a diketone compound, a sulfonium borate compound, a diazo compound, an imidazole compound, a biimidazole compound, or the like.

In an implementation, the photopolymerization initiator may be included in an amount of about 0.1 wt % to about 5 wt %, e.g., about 0.5 wt % to about 3 wt %, based on a total weight of the photosensitive resin composition. In an implementation, the photopolymerization initiator may be included in an amount of about 1 wt % to about 5 wt %, e.g., about 1.5 wt % to about 3 wt %, based on a total weight of solids constituting the photosensitive resin composition. Including the photopolymerization initiator within the above ranges may help ensure that photopolymerization occurs sufficiently during exposure in the pattern formation process for manufacturing microlenses, resulting in excellent sensitivity and improved transmittance.

### (D) Solvent

The solvent may be a material that is compatible with, but does not react with, the polymer resin, the photopolymerizable monomer, and the photopolymerization initiator.

Examples of the solvent may include alcohols, e.g., methanol, ethanol, or the like; ethers, e.g., dichloroethylether, n-butylether, diisoamylether, methylphenylether, tetrahydrofuran, or the like; glycolethers, e.g., ethylene glycolmonomethylether, ethylene glycolmonoethylether, ethylene glycoldimethylether, or the like; cellosolveacetates, e.g., methylcellosolveacetate, ethylcellosolveacetate, diethylcellosolveacetate, or the like; carbitols, e.g., methylethylcarbitol, diethylcarbitol, diethylene glycolmonomethylether, diethylene glycolmonoethylether, diethylene glycoldimethylether, diethylene glycolethylmethylether, diethylene glycoldiethylether, or the like; propylene glycolalkyletheracetates, e.g., propylene glycolmethyletheracetate, propylene glycolpropyletheracetate, or the like; aromatic hydrocarbons, e.g., toluene, xylene, or the like; ketones, e.g., methylethylketone, cyclohexanone, 4-hydroxy-4-methyl-2-pentanone, methyl-n-propylketone, methyl-n-butylketone, methyl-n-amylketone, 2-heptanone, or the like; saturated aliphatic monocarboxylic acid alkyl esters, e.g., ethyl acetate, n-butyl acetate, isobutyl acetate, or the like; lactate esters, e.g., methyl lactate, ethyl lactate, or the like; oxy acetic acid alkyl esters, e.g., oxy methyl acetate, oxy ethyl acetate, oxy butyl acetate, or the like; alkoxy acetic acid alkyl esters, e.g., methoxy methyl acetate, methoxy ethyl acetate, methoxy butyl acetate, ethoxy methyl acetate, ethoxy ethyl acetate, or the like; 3-oxypropionic acid alkyl esters, e.g., 3-oxymethyl propionate, 3-oxyethyl propionate, or the like; 3-alkoxypropionic acid alkyl esters, e.g., 3-methoxymethyl propionate, 3-methoxyethyl propionate, 3-ethoxyethyl propionate, 3-ethoxymethyl propionate, or the like; 2-oxypropionic acid alkyl esters, e.g., 2-oxymethyl propionate, 2-oxyethyl propionate, 2-oxypropyl propionate, or the like; 2-alkoxypropionic acid alkyl esters, e.g., 2-methoxymethyl propionate, 2-methoxyethyl propionate, 2-ethoxyethyl propionate, 2-ethoxymethyl propionate, or the like; 2-oxy-2-methylpropionic acid esters, e.g., 2-oxy-2-methylmethyl propionate, 2-oxy-2-methylethyl propionate, or the like, monooxy monocarboxylic acid alkyl esters of 2-alkoxy-2-methyl alkyl propionates, e.g., 2-methoxy-2-methylmethyl propionate, 2-ethoxy-2-methylethyl propionate, or the like; esters, e.g., 2-hydroxyethyl propionate, 2-hydroxy-2-methylethyl propionate, hydroxy ethyl acetate, 2-hydroxy-3-methyl methyl butanoate, or the like; ketonate esters, e.g., ethyl pyruvate, or the like. In an implementation, a high boiling point solvent, e.g., N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, 7-butyrolactone, ethylene carbonate, propylene carbonate, phenyl cellosolve acetate, or the like may be also used.

Considering miscibility and reactivity, glycolethers, e.g., ethylene glycolmonoethylether, ethylene glycoldimethylether, ethylene glycoldiethylether, diethylene glycolethylmethylether, or the like; ethylene glycolalkylether acetates, e.g., ethyl cellosolveacetate, or the like; esters, e.g., 2-hydroxyethyl propionate, or the like; carbitols, e.g., diethylene glycolmonomethylether, or the like; propylene glycolalkyletheracetates, e.g., propylene glycolmonomethyl ether acetate, propylene glycolpropyletheracetate, or the like may be used.

The solvent may be included in a balance amount, e.g., about 50 wt % to about 90 wt %, about 60 wt % to about 80 wt %, or about 70 wt % to about 80 wt %, based on a total weight of photosensitive resin composition. Including the solvent within the above ranges may help ensure that the photosensitive resin composition may have an appropriate viscosity and thus processability is improved during a production of a photosensitive resin layer, e.g., a microlens.

### (E) Other Additives

In an implementation, the photosensitive resin composition may further include an additive, e.g., malonic acid, 3-amino-1,2-propanediol, a silane coupling agent, a leveling agent, a surfactant, a polymerization inhibitor, or a combination thereof.

The silane coupling agent may have a reactive substituent, e.g., a vinyl group, a carboxyl group, a methacryloxy group, an isocyanate group, or an epoxy group to improve adhesion to the substrate. However, if a silane coupling agent is used, because the photosensitive resin composition according to some example embodiments is a colorant-free composition, e.g., a transparent photosensitive resin composition, if the refractive index of the polymer resin at 550 nm is not controlled as described above, an effect of improving adhesion to the color filter may not be obtained.

Examples of the silane coupling agent may include, e.g., trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, β-(3,4-epoxycyclohexyl)ethyltrimethoxysilane, or the like. These may be used alone or in a mixture of two or more.

The silane coupling agent may be included in an amount of about 0.01 parts by weight to about 10 parts by weight, based on 100 parts by weight of the photosensitive resin composition. Including the silane coupling agent within the above range may help ensure that adhesion, storage capability, and the like are improved.

In an implementation, the photosensitive resin composition may further include a surfactant, e.g., a fluorine surfactant or a silicone surfactant, to help improve coating properties and prevent defect formation.

Examples of the fluorine surfactant may include a commercial fluorine surfactant such as BM-1000™, BM-1100™, or the like of BM Chemie Inc.; MEGAFACE® F-142D™, MEGAFACE® F-172™, MEGAFACE® F-173™, MEGAFACE® F-183™, MEGAFACE® F-554™, or the like of Dainippon Ink Kagaku Kogyo Co., Ltd.; FLUORAD® FC-135™, FLUORAD® FC-170C™, FLUORAD® FC-430™, FLUORAD® FC-431™, or the like of SUMITOMO 3M Co., Ltd.; SURFLON S-112™, SURFLON S-113™, SURFLON S-131™, SURFLON S-141™, SURFLON S-145™, or the like of Asahi Glass Co., Ltd.; SH-28PA™, SH-190™, SH-193™, SZ-6032™, SF-8428™, or the like of Toray Silicone Co., Ltd.

The silicone surfactant may be a commercial silicone surfactant, e.g., BYK-307™, BYK-333™, BYK-361N™, BYK-051™, BYK-052™, BYK-053™, BYK-067A™, BYK-077™, BYK-301™, BYK-322™, BYK-325™, and the like of BYK Chem.

The surfactant may be used in an amount of about 0.001 parts by weight to about 5 parts by weight, based on 100 parts by weight of the photosensitive resin composition. Including the surfactant within the above range may help ensure that coating uniformity may be secured, a stain may not be produced, and wetting on an IZO substrate or a glass substrate is improved.

The polymerization inhibitor may include a catechol compound. In an implementation, the photosensitive resin composition according to some example embodiments may further include the catechol compound and room temperature crosslinking may be prevented during exposure to light after coating the photosensitive resin composition.

In an implementation, the catechol compound may include catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum.

The catechol compound may be used in the form of a dispersion and the polymerization inhibitor in the form of the dispersion may be included in an amount of about 0.001 wt % to about 3 wt %, e.g., about 0.01 wt % to about 1 wt %, based on a total weight of the photosensitive resin composition. By including the polymerization inhibitor within the above ranges, it is possible to address the issue of aging at ambient temperature and to help prevent deterioration of sensitivity and surface peeling.

In an implementation, the photosensitive resin composition may include other additives, e.g., a stabilizer, or the like, in a suitable amount, unless they deteriorate properties of the photosensitive resin composition.

The photosensitive resin composition according to some example embodiments may be either positive or negative. In an implementation, the composition may be negative to completely remove residues in regions where a pattern is exposed after exposing and developing the composition having light blocking properties.

In an implementation, the photosensitive resin composition according to some example embodiments may have a refractive index (at 550 nm) of greater than or equal to about 1.62, for example, a refractive index (at 550 nm) of greater than or equal to about 1.62 and less than about 1.66. If the refractive index at 550 nm of the photosensitive resin composition including the polymer resin is controlled as described above, it can be advantageous for improving developability and fine patternability.

Some example embodiments provide a photosensitive resin layer manufactured by low-temperature curing, exposure, and development of the aforementioned photosensitive resin composition. Compared to some LCD or semiconductor processes, the difference may be that the post-curing (post-baking) process may be unnecessary.

A method of manufacturing the photosensitive resin layer is as follows.

### (1) Coating and Film Formation (Low-Temperature Curing)

The photosensitive resin composition may be coated to have a desired thickness on a substrate such as a silicon wafer or the like which undergoes a predetermined pretreatment, using a spin or slit coating method, a roll coating method, a screen-printing method, an applicator method, or the like, and may be heated at about 100° C. for about 1 minute to 10 minutes to remove a solvent and thereby to form a photosensitive resin layer. Through this step, it may be possible to improve image quality, or the like.

### (2) Exposure

After disposing a mask to form a desired pattern on the obtained photosensitive resin layer, exposure may be performed by irradiating an actinic ray of i-line. As a light source used for irradiation, a low-pressure mercury lamp, a high-pressure mercury lamp, an ultra-high pressure mercury lamp, a metal halide lamp, an argon gas laser, or the like may be used. In an implementation, an X-ray, an electron beam, or the like may be used.

The exposure may use, e.g., a light dose of 500 mJ/cm² or less (with a 365 nm sensor) when a high-pressure mercury lamp is used. In an implementation, the light dose may vary depending on types of each component, a combination ratio thereof, and a dry film thickness. Through this step, fine adjustment of the pixel size is possible, enabling high-resolution implementation.

### (3) Development

In the development method, following the exposure step, an alkaline aqueous solution may be used as a developer to dissolve and remove unnecessary parts, leaving only the exposed parts remaining to form a pattern. Through this step, a profile may be formed to realize high resolution, and color uniformity may be secured to improve clarity.

Some example embodiments provide a display device including the photosensitive resin layer. The display device may be a micro organic light emitting diode (OLED) display device.

The micro organic light emitting diode (OLED) display device may include an OLED substrate deposited on a silicon wafer and a color filter layer located on the OLED substrate and converting white light generated from the OLED substrate into a plurality of color lights, wherein the color filter layer may include a red color filter, a green color filter, and a blue color filter. And, the photosensitive resin layer, i.e., the microlens layer, may be located on the OLED substrate and color filter layer. That is, the microlens layer may surround the color filter layer on the OLED substrate.

In an implementation, the micro organic light emitting diode (OLED) display device may include an OLED substrate on a silicon wafer, an inorganic layer stacked on the OLED substrate, a color filter layer stacked on the inorganic layer and converting white light generated from the OLED substrate into a plurality of color lights, and the color filter layer may include a red color filter, a green color filter, and a blue color filter. And, the photosensitive resin layer, i.e., the microlens layer, may be located on the inorganic layer and the color filter layer. That is, the microlens layer may surround the color filter layer on the inorganic layer.

Referring to the FIGURE, in an implementation, the micro organic light emitting diode (OLED) display device may include an OLED substrate deposited on a silicon wafer, an inorganic layer stacked on the OLED substrate, an adhesive protection layer stacked on the inorganic layer, and a color filter layer stacked on the adhesive protection layer and converting white light generated from the OLED substrate into a plurality of color lights, wherein the color filter layer may include a red color filter, a green color filter, and a blue color filter. And, the photosensitive resin layer, i.e., the microlens layer, may be located on the adhesive protection layer and the color filter layer. That is, the microlens layer may surround the color filter layer on the adhesive protection layer.

An OLED substrate in which OLEDs are deposited on a glass or polyimide substrate has been used by some display devices, but the micro OLED display device according to some example embodiments may be more advantageous in implementing a micro display because the OLED is deposited on a silicon wafer. These micro displays are in the spotlight as next-generation displays, and the micro displays are expected to be applied to devices such as MR.

The micro OLED display device with the described structure can be driven on a pixel basis by depositing WOLED on a highly integrated silicon wafer, and it is easy to control the transmission wavelength through a color filter layer patterned with a resolution of less than or equal to about 3 μm, enabling high color reproduction and securing high resolution.

In an implementation, the adhesive protection layer may have a thickness of less than or equal to 1 μm. In this case, the above-mentioned effects, e.g., the effects of improving adhesion to the color filter and improving residue characteristics, may be further maximized. In an implementation, the color filter layer may have a thickness of about 1.1 μm to about 1.6 μm.

If the thickness of the color filter layer is controlled as above, it may be more advantageous to implement a micro OLED display device. In an implementation, the inorganic layer may have a thickness of less than or equal to about 2 μm. Even with WOLED, light does not always diffuse in the direction perpendicular to the OLED substrate, so that color mixing of red, green, and blue may occur. Therefore, an inorganic layer may be deposited on the OLED substrate to prevent such color mixing. However, because the color mixing is not completely prevented even by depositing an inorganic layer, in some example embodiments, subtle light leakage phenomenon may be prevented by thinning the inorganic layer, e.g., controlling the thickness of the inorganic layer to less than or equal to about 2 μm.

In the end, the photosensitive resin composition according to some example embodiments allows the production of a cured layer only through low-temperature (100° C.) curing during prebaking and i-line photocuring, as described above, and therefore there may be a significant difference in resolution that can be implemented compared to conventional display devices.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples

### Preparation of Polymer Resin

### Preparation Example 1: Synthesis of Material Represented by Chemical Formula 5

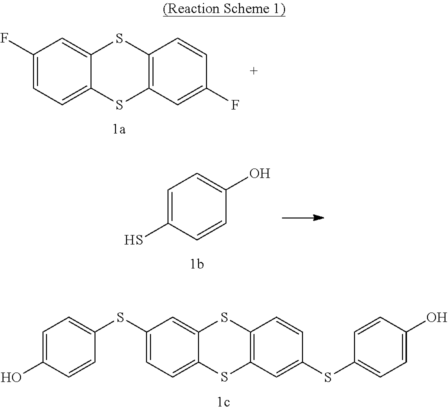 [SMILES: Fc1ccc2c(c1)Sc1ccc(F)cc1S2 ; Oc1ccc(S)cc1 ; Oc1ccc(Sc2ccc3c(c2)Sc2ccc(Sc4ccc(O)cc4)cc2S3)cc1]

Compound 1a (10.0 mmol) was added to 30.0 mL of DMF (N,N-dimethylformamide) together with Compound 1b (4.00 mmol) and potassium carbonate (K₂CO₃, 4.00 mmol), and the reaction was refluxed overnight. After confirming the exhaustion of Compound 1a through thin-layer chromatography, the reaction mixture was added to distilled water to generate a precipitate. After separating the substance through vacuum filtration, the substance was washed with distilled water and recrystallized using toluene to obtain Compound 1c.

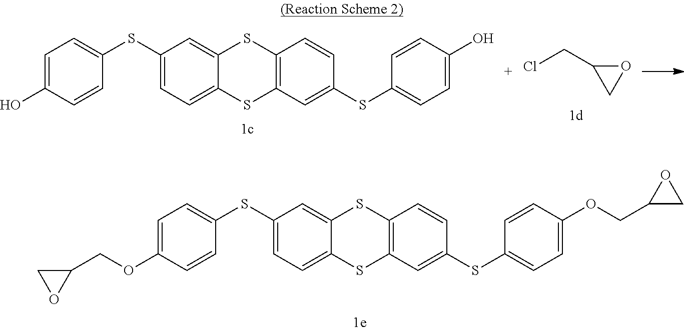 [SMILES: Oc1ccc(Sc2ccc3c(c2)Sc2ccc(Sc4ccc(O)cc4)cc2S3)cc1 ; ClCC1CO1 ; c1cc(Sc2ccc3c(c2)Sc2ccc(Sc4ccc(OCC5CO5)cc4)cc2S3)ccc1OCC1CO1]

Compound 1c (5.00 mmol) was added to 20.0 mL of 1,4-dioxane/H₂O (v/v=1/1) together with Compound 1d (50.0 mmol) and potassium carbonate (K₂CO₃, 25.0 mmol), and stirred overnight at ambient temperature. After confirming the exhaustion of Compound 1c through thin-layer chromatography, the reaction mixture was added to distilled water to generate a precipitate. The substance was separated through pressure filtration, washed with distilled water, and dried overnight in a vacuum oven. Compound 1e was obtained by recrystallization using toluene.

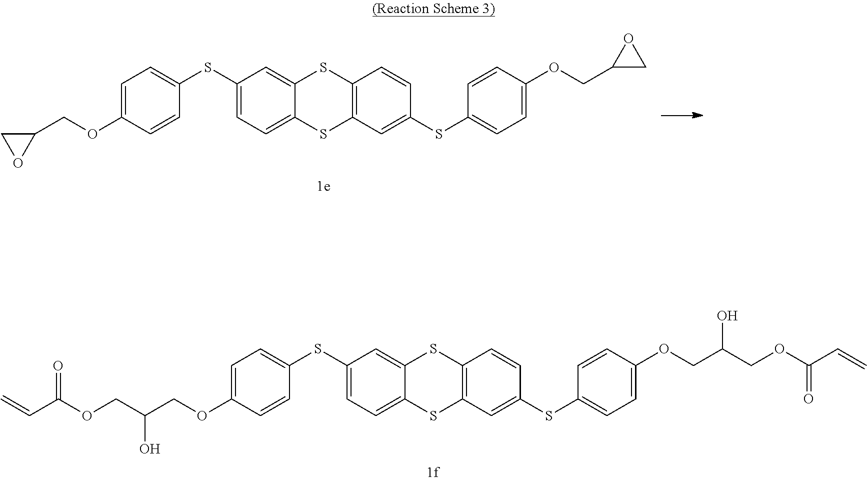 [SMILES: c1cc(Sc2ccc3c(c2)Sc2ccc(Sc4ccc(OCC5CO5)cc4)cc2S3)ccc1OCC1CO1 ; C=CC(=O)OCC(O)COc1ccc(Sc2ccc3c(c2)Sc2ccc(Sc4ccc(OCC(O)COC(=O)C=C)cc4)cc2S3)cc1]

Compound 1e (10.0 mmol) was added to 30.0 mL of toluene together with acrylic acid (30.0 mmol), tetrabutylphosphonium bromide (TBPB, 1.00 mmol), and BHT (butylated hydroxytoluene, 0.50 mmol), and refluxing was performed overnight. After removing the solvent under reduced pressure, Compound 1f was obtained by purification through column chromatography (eluent: n-hexane/EtOAc).

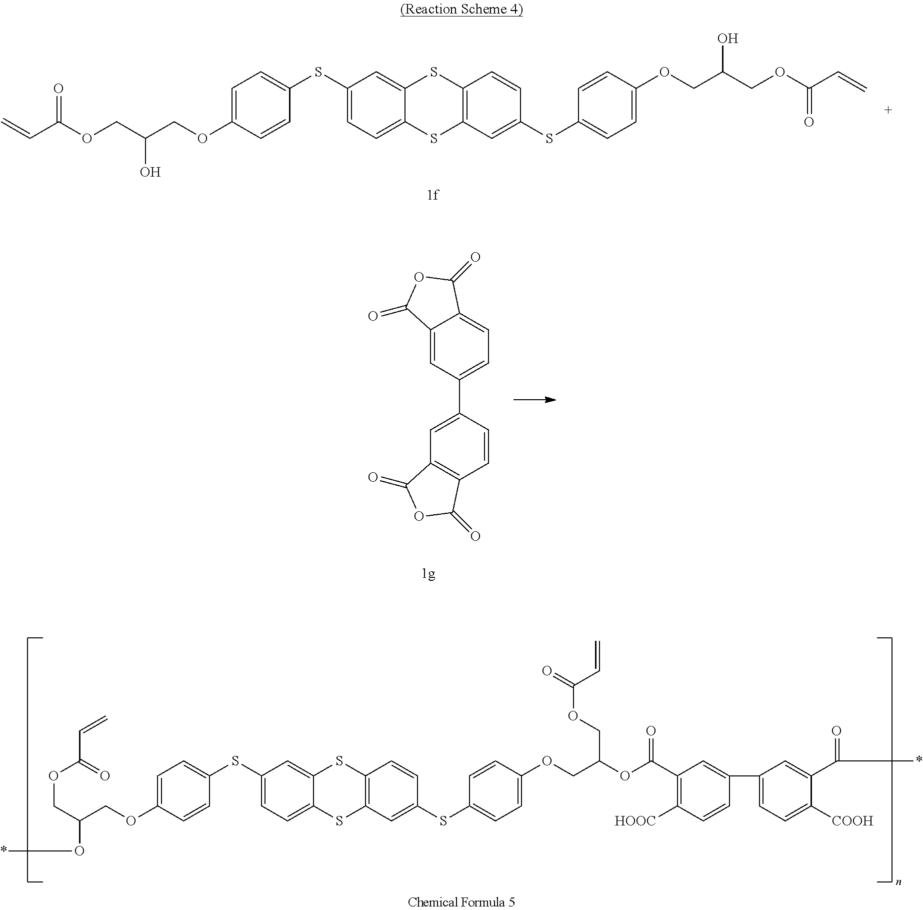

Compound 1f (10.0 mmol) with Compound 1g (11.0 mmol), BHT (butylated hydroxytoluene, 0.5 wt %), and DBU (0.50 mmol) was added to 30.0 mL of cyclohexanone, and the reaction mixture was heated to 110° C. and then stirred for 6 hours to prepare a polymer resin (a weight average molecular weight: 4,900 g/mol) including a repeating structural unit represented by Chemical Formula 5. The refractive index at 550 nm was 1.69.

### Preparation Example 2: Synthesis of Material Represented by Chemical Formula 6

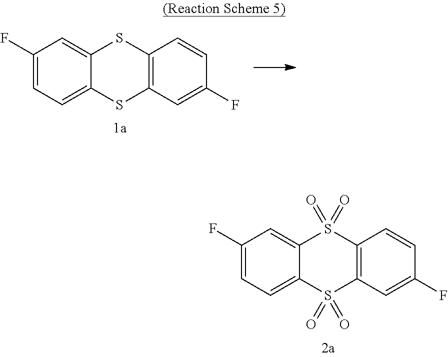 [SMILES: Fc1ccc2c(c1)Sc1ccc(F)cc1S2 ; O=S1(=O)c2ccc(F)cc2S(=O)(=O)c2ccc(F)cc21]

Compound 1a (10.0 mmol) was added to 1.50 mL of acetic acid, and an excessive amount of 30% hydrogen peroxide was added thereto at ambient temperature. The reaction mixture was stirred at 120° C. overnight and then, extracted by using DCM (dichloromethane). After passing an organic layer therefrom through MgSO₄ and removing a solvent under a reduced pressure, Compound 2a was obtained by purification through column chromatography (eluent: DCM/n-hexane).

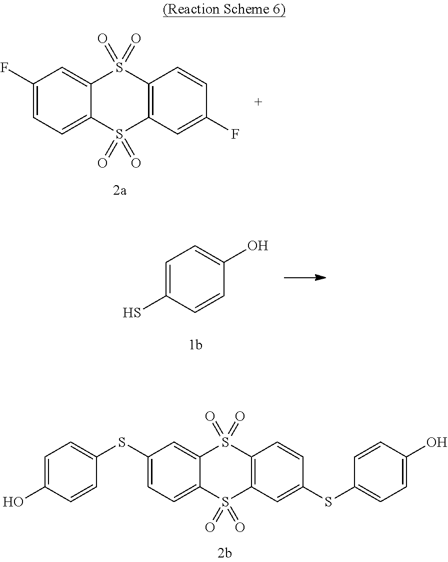 [SMILES: O=S1(=O)c2ccc(F)cc2S(=O)(=O)c2ccc(F)cc21 ; Oc1ccc(S)cc1 ; O=S1(=O)c2ccc(Sc3ccc(O)cc3)cc2S(=O)(=O)c2ccc(Sc3ccc(O)cc3)cc21]

Compound 2b was synthesized in the same manner as in the method of synthesizing the compound 1c except that Compound 2a was used instead of Compound 1a.

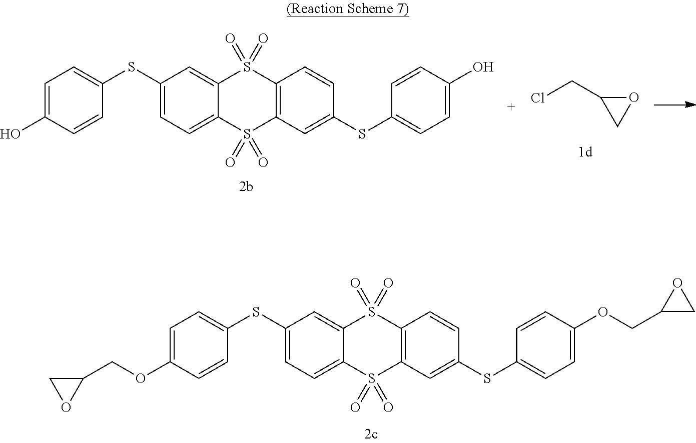 [SMILES: O=S1(=O)c2ccc(Sc3ccc(O)cc3)cc2S(=O)(=O)c2ccc(Sc3ccc(O)cc3)cc21 ; ClCC1CO1 ; O=S1(=O)c2ccc(Sc3ccc(OCC4CO4)cc3)cc2S(=O)(=O)c2ccc(Sc3ccc(OCC4CO4)cc3)cc21]

Compound 2c was synthesized in the same manner as in the method of synthesizing Compound 1e except that Compound 2b was used instead of Compound 1c.

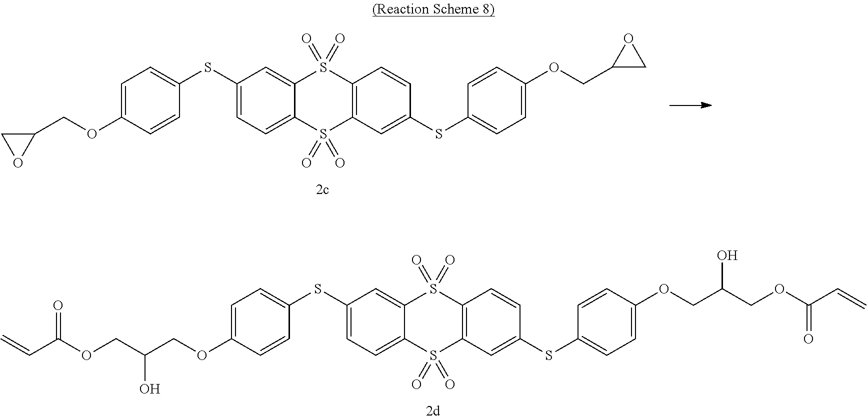 [SMILES: O=S1(=O)c2ccc(Sc3ccc(OCC4CO4)cc3)cc2S(=O)(=O)c2ccc(Sc3ccc(OCC4CO4)cc3)cc21 ; C=CC(=O)OCC(O)COc1ccc(Sc2ccc3c(c2)S(=O)(=O)c2ccc(Sc4ccc(OCC(O)COC(=O)C=C)cc4)cc2S3(=O)=O)cc1]

Compound 2d was synthesized in the same manner as in the method of synthesizing Compound 1f except that Compound 2c was used instead of Compound 1e.

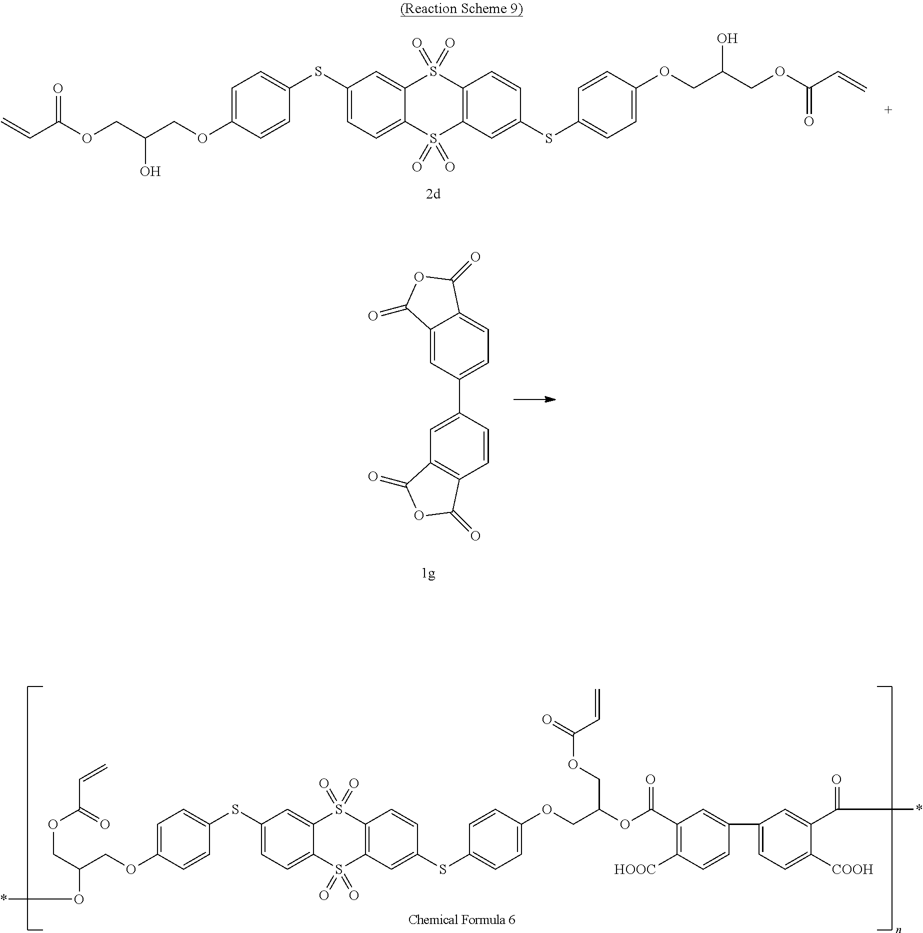

A polymer resin (a weight average molecular weight: 4,600 g/mol) including a repeating structural unit represented by Chemical Formula 6 was synthesized in the same manner as in the method of synthesizing Compound 1f except that Compound 2d was used instead of Compound 1f. The refractive index at 550 nm was 1.68.

### Preparation Example 3: Synthesis of Material Represented by Chemical Formula 7

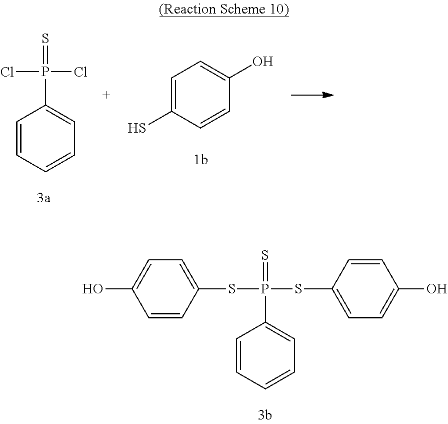 [SMILES: S=P(Cl)(Cl)c1ccccc1 ; Oc1ccc(S)cc1 ; Oc1ccc(SP(=S)(Sc2ccc(O)cc2)c2ccccc2)cc1]

Compound 3a (10.0 mmol) and Compound 1b (20.0 mmol) with triethylamine (22.0 mmol) were dissolved in 40.0 mL of THF (tetrahydrofuran) at 0° C. and then, stirred at ambient temperature for 2 hours. After removing the solvent under a reduced pressure, the reaction mixture was dissolved in DCM (dichloromethane), and after washing the obtained solution with a 1 N HCl aqueous solution, the organic layer was passed through MgSO₄. The obtained organic layer was concentrated under a reduced pressure to obtain Compound 3b, which was used in the subsequent reaction without an additional purification process.

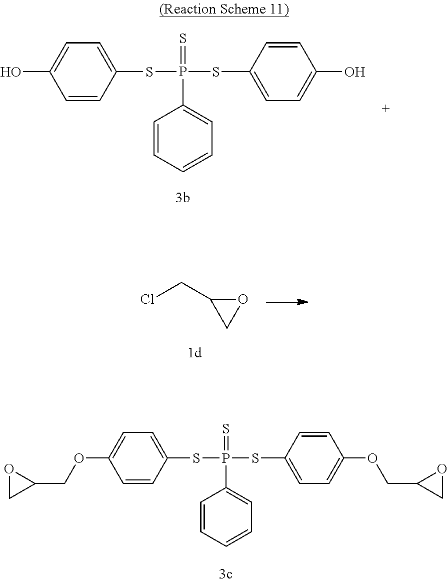 [SMILES: Oc1ccc(SP(=S)(Sc2ccc(O)cc2)c2ccccc2)cc1 ; ClCC1CO1 ; S=P(Sc1ccc(OCC2CO2)cc1)(Sc1ccc(OCC2CO2)cc1)c1ccccc1]

Compound 3c was synthesized in the same manner as in the method of synthesizing Compound 1e except that Compound 3b was used instead of Compound 1c.

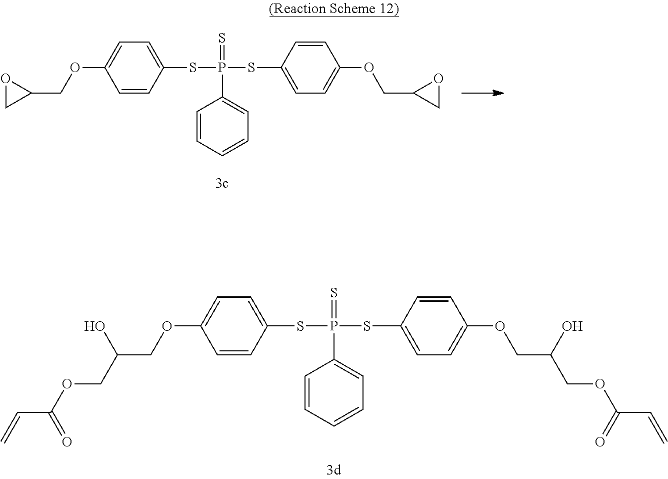 [SMILES: S=P(Sc1ccc(OCC2CO2)cc1)(Sc1ccc(OCC2CO2)cc1)c1ccccc1 ; C=CC(=O)OCC(O)COc1ccc(SP(=S)(Sc2ccc(OCC(O)COC(=O)C=C)cc2)c2ccccc2)cc1]

Compound 3d was synthesized in the same manner as in the method of synthesizing Compound 1f except that Compound 3c was used instead of Compound 1e.

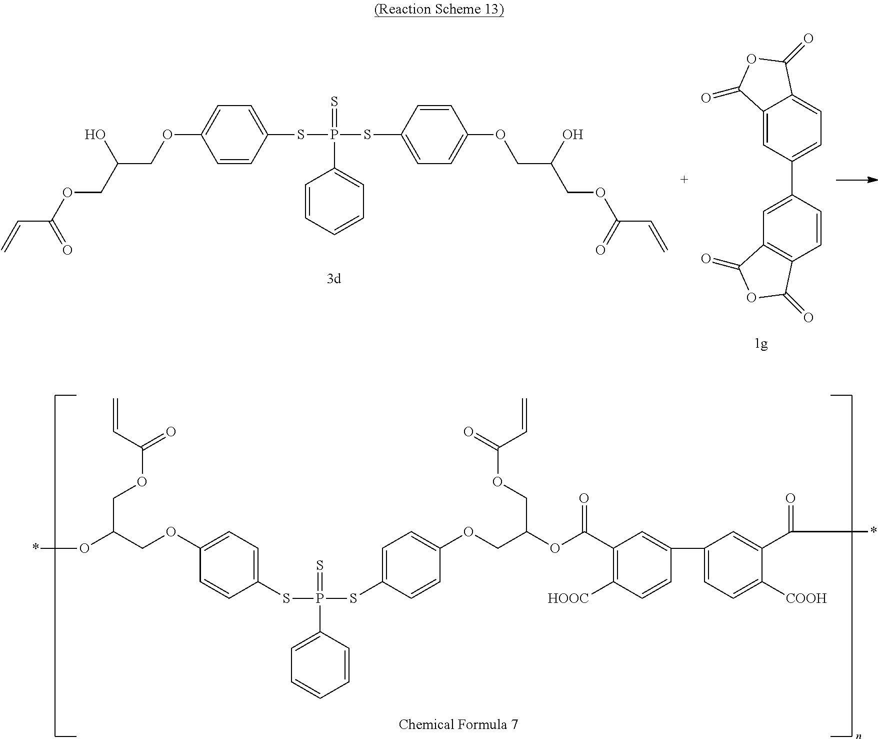

A polymer resin (weight average molecular weight: 4,300 g/mol) including a repeating structural unit represented by Chemical Formula 7 was synthesized in the same manner as in the method of synthesizing the material represented by Chemical Formula 5 except that Compound 3d was used instead of Compound 1f. The refractive index at 550 nm was 1.66.

### Preparation Example 4: Synthesis of Material Represented by Chemical Formula 8

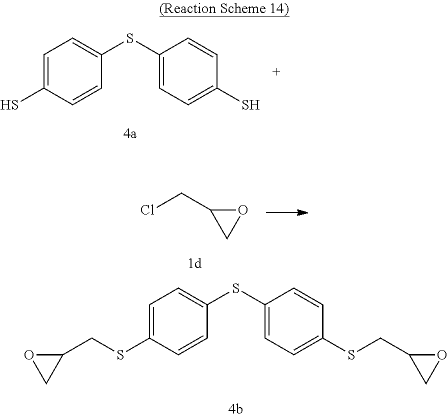 [SMILES: Sc1ccc(Sc2ccc(S)cc2)cc1 ; ClCC1CO1 ; c1cc(Sc2ccc(SCC3CO3)cc2)ccc1SCC1CO1]

Compound 4b was synthesized in the same manner as in the method of synthesizing Compound 1e except that Compound 4a was used instead of Compound 1c.

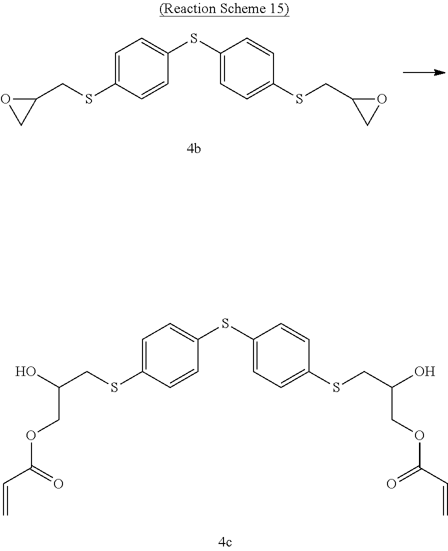 [SMILES: c1cc(Sc2ccc(SCC3CO3)cc2)ccc1SCC1CO1 ; C=CC(=O)OCC(O)CSc1ccc(Sc2ccc(SCC(O)COC(=O)C=C)cc2)cc1]

Compound 4c was synthesized in the same manner as in the method of synthesizing Compound 1f except that Compound 4b was used instead of Compound 1e.

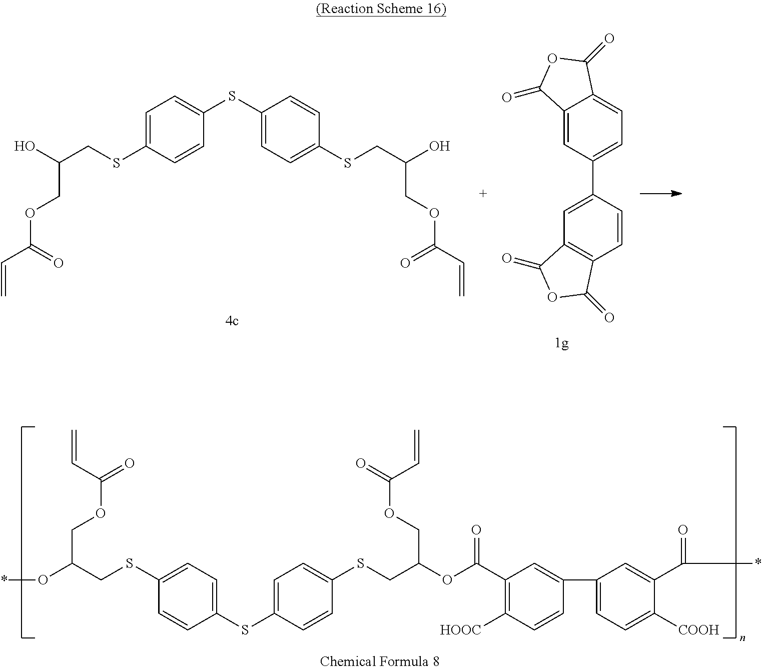

A polymer resin (weight average molecular weight: 5,100 g/mol) including a repeating structural unit represented by Chemical Formula 8 was synthesized in the same manner as in the method of synthesizing the material Chemical Formula 5 except that Compound 4c was used instead of Compound 1f. The refractive index at 550 nm was 1.67.

### Comparative Preparation Example 1: Synthesis of Material Represented by Chemical Formula C-1

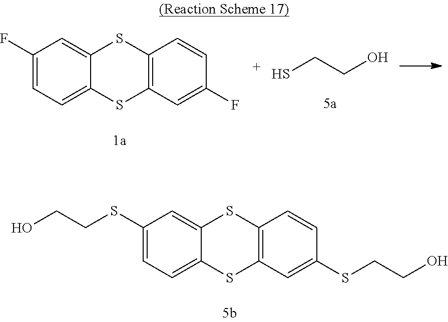

A solution of Compound 5a (25.0 mmol) and potassium tert-butoxide (KOt-Bu, 25.0 mmol) dissolved in 25.0 mL of DMF (N,N-dimethylformamide) was stirred at ambient temperature for 1 hour. Afterwards, Compound 1a (10.0 mmol) was added, the temperature was raised to 120° C., and stirred for 12 hours. After confirming the exhaustion of Compound 1a through thin-layer chromatography, the reaction mixture was added to distilled water to generate a precipitate. After separating the substance through vacuum filtration, the substance was washed with distilled water and recrystallized using toluene to obtain Compound 5b.

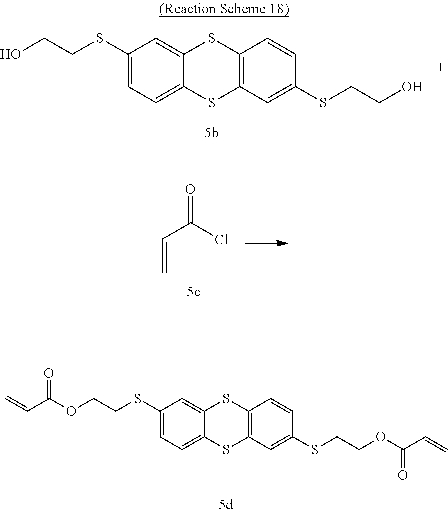

N,N-dimethylaniline (15.0 mmol) was added to Compound 5b (5.00 mmol) dissolved in 30.0 mL of THF (tetrahydrofuran). After the solution was cooled to 0° C., a solution of Compound 5c (20.0 mmol) dissolved in 10.0 mL of THF was slowly added. The reaction mixture was stirred overnight at ambient temperature, and then a saturated aqueous sodium bicarbonate solution was added. The solution was diluted with distilled water and extracted with chloroform. The organic layer was passed through MgSO₄ and concentrated under reduced pressure, and the resultant was purified through column chromatography (eluent: DCM/n-hexane) to obtain Compound 5d.

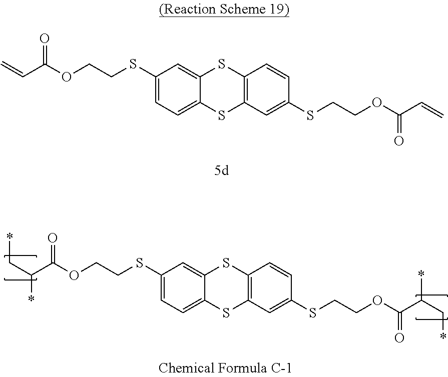

A polymer resin (weight average molecular weight: 14,500 g/mol) including a repeating structural unit represented by Chemical Formula C-1 was synthesized by stirring Compound 5d (3.00 mmol) with diphenyl(2,4,6-trimethylbenzoyl)phosphineoxide (1.5 wt %) at 60° C. for 20 minutes and then, radiating ultraviolet rays thereto with a mercury lamp (Miksa mercury lamp Model M-1S) for 30 minutes. The refractive index at 550 nm was 1.65.

### Comparative Preparation Example 2: Synthesis of Material Represented by Chemical Formula C-2

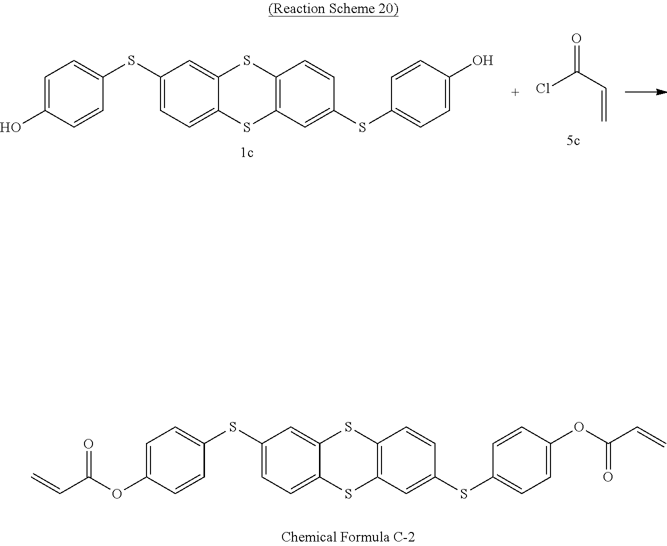

A monomolecular compound represented by Chemical Formula C-2 was prepared in the same manner as the synthesis of Compound 5d, except that Compound 1c was used instead of Compound 5b. The refractive index at 550 nm was 1.66.

### Preparation of Photosensitive Resin Compositions

### Examples 1 to 4 and Comparative Examples 1 and 2

With the compositions shown in Table 1, the photopolymerization initiator was dissolved in a solvent and stirred at room temperature for 2 hours. Here, polymer resin and photopolymerizable monomer were added, stirred at room temperature (25° C.) for 1 hour, and then the entire solution was stirred again for 2 hours. The solution was filtered three times through a 0.45 μm filter to remove impurities, thereby producing each photosensitive resin composition.

TABLE 1
(unit: wt %)

| | | Ex. | Ex. | Ex. | Ex. | Comp. | Comp. |
|---|---|---|---|---|---|---|---|
| | | 1 | 2 | 3 | 4 | Ex. 1 | Ex. 2 |
| (A) Polymer | (A-1) | 17.5 | — | — | — | — | — |
| resin | (A-2) | — | 17.5 | — | — | — | — |
| | (A-3) | — | — | 17.5 | — | — | — |
| | (A-4) | — | — | — | 17.5 | — | — |
| | (A-5) | — | — | — | — | 17.5 | — |
| | (A-6) | — | — | — | — | — | 17.5 |

| | | | | | | |
|---|---|---|---|---|---|---|
| (B) Photopolymerizable | 7 | 7 | 7 | 7 | 7 | 7 |
| monomer | | | | | | |
| (C) Photopolymerization | 1 | 1 | 1 | 1 | 1 | 1 |
| initiator | | | | | | |
| (D) Solvent | 74.5 | 74.5 | 74.5 | 74.5 | 74.5 | 74.5 |

(A) Polymer resin (monomolecular compound)
(A-1) Polymer resin of Preparation Example 1
(A-2) Polymer resin of Preparation Example 2
(A-3) Polymer resin of Preparation Example 3
(A-4) Polymer resin of Preparation Example 4
(A-5) Polymer resin of Comparative Preparation Example 1
(A-6) Polymer resin of Comparative Preparation Example 2
(B) Photopolymerizable Monomer
Ethoxylated bisphenyl fluorene diacrylate (BPF-022L, Hannong Chemicals Inc.)
(C) Photopolymerization Initiator
Oxime initiator (SPI-03, Samyang Corporation)
(D) Solvent
Propylene glycol monomethyl ether acetate (PGMEA, Daicel Corporation)

### Evaluation

After confirming that the photosensitive resin compositions according to Examples 1 to 4 and Comparative Examples 1 and 2 were all transparent, their refractive indices at 550 nm were measured. Thereafter, each of these was coated on an 8-inch silicon wafer using a SEMES K-SPIN at an rpm capable of exhibiting a similar thickness, followed by soft baking on a 100° C. hot plate, and pattern exposure was performed under the exposure conditions of (Dose: 200 ms/Focus: −0.3) on a i-line stepper made by Nikon Corp. In the exposure process, after measuring a thickness by using TENCOR, the coated substrate was developed to reveal the patterns. Herein, an EHD-100S solution (TMAH) was used as a developer, and time (seconds) (BP) taken for the patterns to appear was measured.

The patterns on the substrate completed with the development were checked with respect to sensitivity and residues through CD-SEM made by Hitachi, Ltd. The pattern was confirmed to be a 96 μm negative pattern, and a large area of residue was confirmed using an Olympus optical microscope, and the results are shown in Table 2. The evaluation criteria for developability and pattern linearity are shown in Table 3.

TABLE 2

| | Example | Example | Example | Example | Comparative | Comparative |
|---|---|---|---|---|---|---|
| | 1 | 2 | 3 | 4 | Example 1 | Example 2 |
| Refractive index | 1.65 | 1.64 | 1.62 | 1.64 | 1.61 | 1.60 |
| Development time (seconds) | 10 | 10 | 10 | 10 | Undeveloped | Undeveloped |
| Developability | ⊚ | ⊚ | ⊚ | ⊚ | X | X |
| Pattern linearity | ⊚ | ⊚ | ◯ | ◯ | X | X |

TABLE 3

| | Developability | Pattern linearity |
|---|---|---|
| ⊚ | No residue | Very good linearity |
| ◯ | Only slight residue is present | Excellent linearity |
| | around the pattern | |
| Δ | All region residues occur | Lack of linearity |
| X | Undeveloped | Very inferior linearity |

Through the evaluation, the photosensitive resin compositions according to some example embodiments are a transparent photosensitive resin composition that have excellent pattern linearity and residue characteristics even with low temperature curing, making it suitable for use as a microlens surrounding a color filter in a micro OLED.

By way of summation and review, in the micro OLED display panels which may have 10 times smaller pixels than general OLED display panels, red (R)/green (G)/blue (B) light emitting layers may be difficult to achieve by using conventional FMM (Fine Metal Mask) technology. In other words, if the conventional liquid crystal displays are applied to devices for VR, AR, and the like, the color filters may have too large a pattern size to increase resolution.

Accordingly, OLEDoS (OLED on Silicon) technology has recently been introduced to achieve high resolution of about 4000 ppi or more. The corresponding technology uses OLED deposited on a silicon wafer as a backlight to pattern color filters thereon. While some color filters used for liquid crystal displays may be formed by mounting about 100 μm patterns on a glass and curing it through an exposure process and a post-baking process at a high temperature of about 230° C. or more, the color filters mounted on OLEDoS may not go through the high temperature process due to the use of OLEDs and should be cured at a low temperature, and in addition, micro-patterning may be important in order to increase resolution. Because the VR and AR devices may be small in size, the micro-patterning may be essential to achieve desired resolution.

However, because curing only occurs at low temperatures (below 100° C.), color filters made from existing materials may lack developability and patternability. Therefore, research is continuing on a low-temperature curable transparent material that has excellent color filter adhesion as well as developability and fine patternability.

A photosensitive resin composition according to some example embodiments may be a transparent photosensitive resin composition that can be cured at a low temperature of 100° C. or lower, may have excellent adhesion to a color filter, and may have excellent developability and fine patternability. Because the aforementioned effects may be achieved even with a pre-bake temperature of 100° C. or lower and only photocuring (i-line exposure), the composition may be suitably applied as a microlens layer (micro lens array) in a micro OLED display device capable of implementing a micropattern.

Some example embodiments provide a photosensitive resin composition that is sufficiently cured even at low temperatures, is transparent, has excellent adhesion to a color filter, and has excellent developability and fine patternability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a polymer resin having a refractive index of greater than or equal to about 1.66;
a photopolymerizable monomer;
a photopolymerization initiator; and
a solvent,
wherein:
the polymer resin has a repeating structural unit, and
the structural unit includes a moiety derived from an acid dianhydride.

2. The photosensitive resin composition as claimed in claim 1, wherein the structural unit further includes a moiety including one or more sulfur atoms.

3. The photosensitive resin composition as claimed in claim 2, wherein:
the moiety including one or more sulfur atoms includes a structure represented by one of Chemical Formula 1 to Chemical Formula 3: 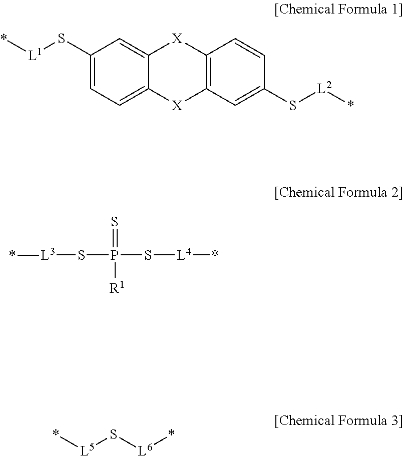
in Chemical Formula 1 to Chemical Formula 3,
X is *—S—* or *—S(═O)₂—*,
R1 is a substituted or unsubstituted C1 to C20 alkyl group or a substituted or unsubstituted C6 to C20 aryl group, and
L1 to L6 are each independently a substituted or unsubstituted C1 to C20 alkylene group or a substituted or unsubstituted C6 to C20 arylene group.

4. The photosensitive resin composition as claimed in claim 2, wherein the moiety including one or more sulfur atoms includes one of Chemical Formula 1-1, Chemical Formula 1-2, Chemical Formula 2-1 or Chemical Formula 3-1:

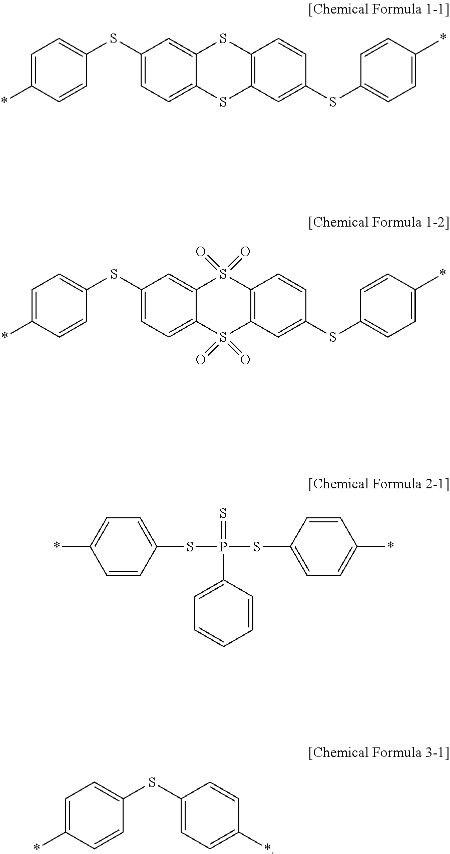

5. The photosensitive resin composition as claimed in claim 1, wherein:
the moiety derived from the acid dianhydride includes a structure represented by Chemical Formula 4-1 or Chemical Formula 4-2: 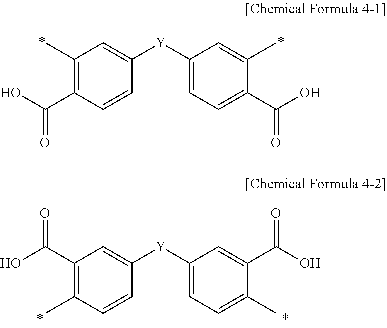
in Chemical Formula 4-1 and Chemical Formula 4-2 Y is a single bond or *—C(═O)—*.

6. The photosensitive resin composition as claimed in claim 1, wherein the repeating structural unit in the polymer resin is represented by one of Chemical Formula 5 to Chemical Formula 8:

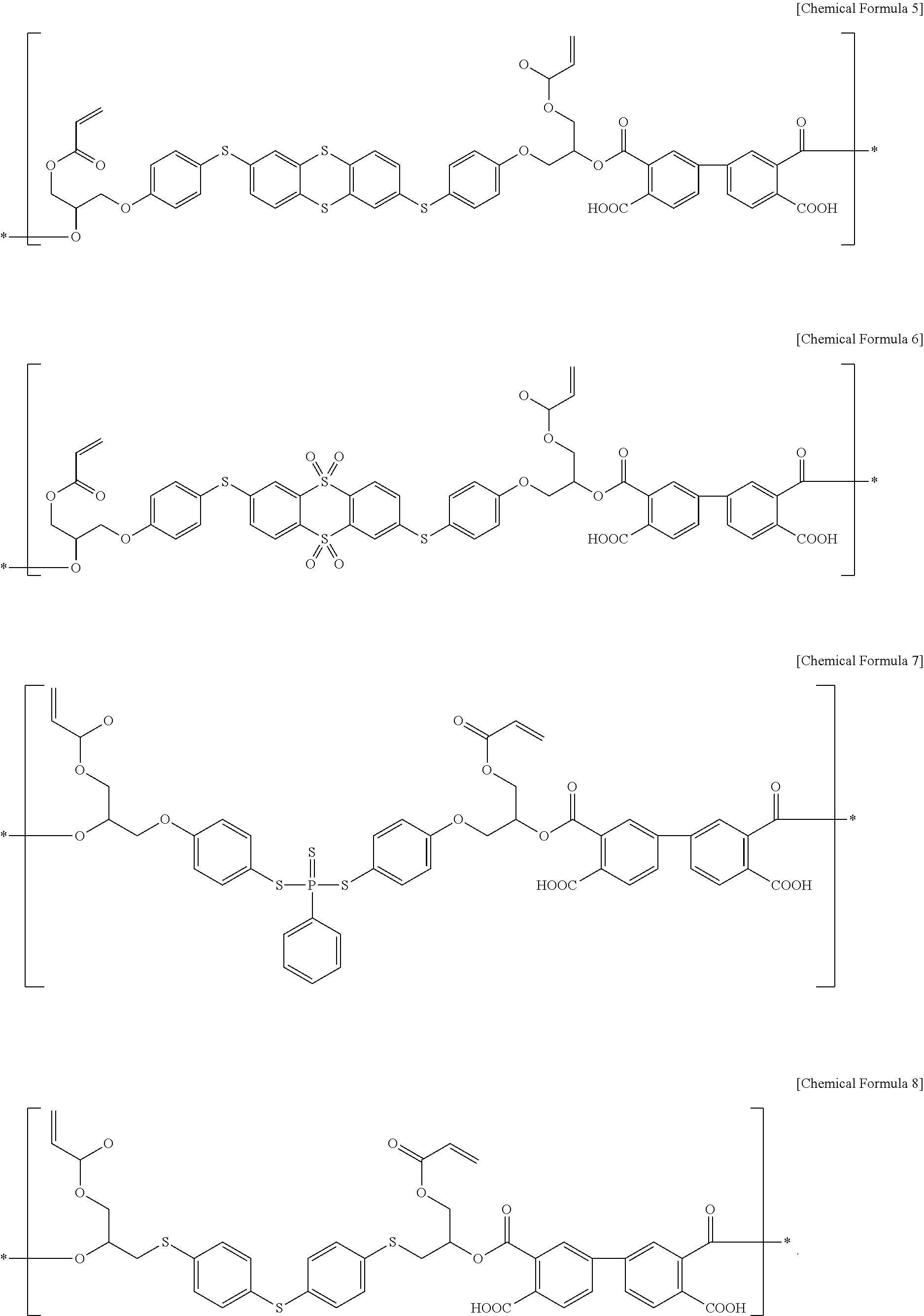

7. The photosensitive resin composition as claimed in claim 1, wherein the polymer resin is included in an amount of about 10 wt % to about 30 wt %, based on a total weight of the photosensitive resin composition.

8. The photosensitive resin composition as claimed in claim 1, wherein the polymer resin has a weight average molecular weight of about 20,000 g/mol to about 80,000 g/mol.

9. The photosensitive resin composition as claimed in claim 1, wherein the photosensitive resin composition includes, based on a total weight of the photosensitive resin composition:
about 10 wt % to about 30 wt % of the polymer resin;
about 3 wt % to about 15 wt % of the photopolymerizable monomer; and
about 0.1 wt % to about 5 wt % of the photopolymerization initiator.

10. The photosensitive resin composition as claimed in claim 1, further comprising malonic acid, 3-amino-1,2-propanediol, a silane coupling agent, a leveling agent, a surfactant, a polymerization inhibitor, or a combination thereof.

11. A photosensitive resin layer manufactured using the photosensitive resin composition as claimed in claim 1.

12. A display device comprising the photosensitive resin layer as claimed in claim 11.

13. The display device as claimed in claim 12, wherein:
the display device is a micro OLED display device including an OLED substrate on a silicon wafer and a color filter layer located on the OLED substrate and configured to convert white light generated from the OLED substrate into a plurality of color lights,
the photosensitive resin layer is located on the OLED substrate and color filter layer, and
the color filter layer includes a red color filter, a green color filter, and a blue color filter.

14. A method of manufacturing a photosensitive resin layer, the method comprising:
coating the photosensitive resin composition as claimed in claim 1;
prebaking at a temperature of about 100° C. or lower after the coating; and
exposing to i-line after the prebaking, and
developing after the exposing.

15. A photosensitive resin composition, comprising:
a polymer resin having a refractive index of greater than or equal to about 1.62;
a photopolymerizable monomer;
a photopolymerization initiator; and
a solvent,
wherein:
the polymer resin has a repeating structural unit, and
the structural unit includes a moiety derived from an acid dianhydride.
